(19) United States
(12) Patent Application Publication
(10) Pub. No.: US 2026/0343759 A1
(43) Pub. Date: Oct. 29, 2026

(54) Multi-Stage Angle Adjustable Sliding Dual-Screen CPU Liquid Cooling Heat Dissipation Device

(71) Applicant: Shanghai TRYX Technology Co., Ltd., Shanghai (CN)

(72) Inventors: Hang CUI, Shanghai (CN); Xingzhe WANG, Shanghai (CN); Xiaoyang WANG, Shanghai (CN)

(21) Appl. No.: 19/435,342

(22) Filed: Dec. 29, 2025

(30) Foreign Application Priority Data
Apr. 28, 2025 (CN) 202520825231.X

(51) Int. Cl. H05K 5/02; H05K 7/20

(52) U.S. Cl. CPC H05K 5/0226; H05K 7/20963

(57) ABSTRACT

A multi-stage angle adjustable sliding dual-screen CPU liquid cooling heat dissipation device, including: a first display screen; a second display screen connected to the first display screen via a rotary support structure; a sliding linkage mechanism cooperating with the rotary support structure, used for achieving multi-stage angle adjustment between the first display screen and the second display screen; and a positioning mechanism disposed on the sliding linkage mechanism. The positioning mechanism achieves tactile detent locking between the first display screen and the second display screen through a spring-ball structure provided thereon. By adopting the multi-stage angle adjustable sliding dual-screen CPU liquid cooling heat dissipation device, an independent dual-screen+slide rail linkage structure is specifically proposed. In the closed state, only the upper screen assembly is displayed, and dual-screen multi-angle positioning, including a fully expanded multimedia mode and a vertical collaboration mode, is achieved. This effectively solves the contradiction between fixed display angles and space utilization in traditional solutions, realizing collaborative optimization of the slidable dual-screen structure and the liquid cooling system.

### CROSS REFERENCE OF RELATED APPLICATIONS

The present application claims the priority of the Chinese utility model patent application which application number is 202520825231.X filed Apr. 28, 2025, and the contents of which are hereby incorporated into this application by reference.

### FIELD OF THE INVENTION

The present technical solution relates to the field of liquid cooling heat dissipation devices, and more particularly to the field of liquid cooling display screens, specifically to a multi-stage angle adjustable sliding dual-screen CPU liquid cooling heat dissipation device.

### BACKGROUND

Existing liquid cooling display screens consist of only a single fixed screen, a curved screen, or two spliced screens, which primarily suffer from the following technical limitations:
1. Fixed screens: For example, CN202110123456A discloses an integrated water block display screen. This solution only supports a single display angle and cannot adjust the viewing angle according to the usage scenario, forcing users to frequently adjust the monitor position in different situations such as standing or sitting.
2. Curved screen solutions: Although capable of expanding the viewing range, they are limited by the rigid structure of the curved screen with a fixed curvature radius (typically≥800 R), preventing physical angle adjustment. Furthermore, a seam blind spot of approximately 3-5 mm exists when two screens are spliced together.
3. Dual-screen splicing structures: While capable of expanding the display area by arranging two display screens side by side, they fail to address the following issues:
   1. Occupied space increases by 40%-60% when the screens are unfolded (compared to a single-screen solution);
   2. Lack of a linkage adjustment mechanism requires separate adjustment of the dual-screen angles, resulting in high operational complexity;
   3. The heat dissipation air flow path is obstructed at the splice joint (tests show a temperature increase of 8-10 °C in the splicing area).

Based on this, addressing the defect problems existing in the current prior art, it is necessary to propose an optimized solution to overcome the deficiencies of the existing technology.

### SUMMARY OF INVENTION

The object of the present invention is to overcome problems such as fixed viewing angles of existing liquid cooling display screens, low space utilization rate of dual-screen splicing, and limited heat dissipation efficiency, and to provide a multi-stage angle adjustable sliding dual-screen CPU liquid cooling heat dissipation device.

To achieve the above object, the multi-stage angle adjustable sliding dual-screen CPU liquid cooling heat dissipation device according to the present invention is specifically as follows:

The multi-stage angle adjustable sliding dual-screen CPU liquid cooling heat dissipation device is characterized in that said device comprises:
a first display screen;
a second display screen connected to the first display screen via a rotary support structure;
a sliding linkage mechanism, cooperating with the rotary support structure, configured to achieve multi-stage angle adjustment between the first display screen and the second display screen; and
a positioning mechanism disposed on the sliding linkage mechanism, wherein the positioning mechanism achieves tactile detent locking between the first display screen and the second display screen through a spring-ball structure provided thereon.

Preferably, the rotary support structure comprises a connecting rod and a rotary shaft, wherein one end of the connecting rod is connected to the rotary shaft, and the other end is hingedly connected to a side wall of the first display screen; and wherein the rotary shaft is disposed at an end of the sliding linkage mechanism and has a built-in damping mechanism.

Preferably, the sliding linkage mechanism comprises:
oppositely disposed slide rails;
sliding rods disposed on the slide rails;
sliding members slidably positioned through the slide rails and the sliding rods, wherein an upper end of the sliding member is hingedly connected to the side wall of the first display screen and drives the first display screen to slide along the slide rails; and
a spring assembly disposed on a lower surface of the slide rails, wherein the spring assembly cooperates with the sliding members to enable tactile detent locking between the first display screen and the second display screen.

More preferably, when the sliding members slide to a side away from the rotary shaft and are engaged at ends of the slide rails, the connecting rods are driven into a locked state by the first display screen, causing the first display screen and the second display screen to be in a first closed detent position.

More preferably, when the sliding members slide to a side close to the rotary shaft and are engaged at terminal ends of the slide rails, the sliding members drive the rotary shaft to rotate, and drive the connecting rods to position the side wall of the first display screen perpendicular to the second display screen, causing the first display screen and the second display screen to be in a second closed detent position.

More preferably, the spring assembly comprises spring posts and spring balls disposed therein; and wherein when the sliding members slide to positions of the spring posts, the spring balls engage with the sliding members, thereby achieving tactile detent locking between the first display screen and the second display screen, and placing the first display screen and the second display screen in a third closed detent position.

More preferably, a V-shaped heat dissipation space is formed between the first display screen and the second display screen.

More preferably, PCB board are installed within both the first display screen and the second display screen.

More preferably, the device is entirely fixed on a lower plastic component, and the lower plastic component is fixed on a liquid cooling head.

By adopting the multi-stage angle adjustable sliding dual-screen CPU liquid cooling heat dissipation device of the present invention, an independent dual-screen+slide rail linkage structure is specifically proposed. In the closed state, only the upper screen assembly is displayed. During side-sliding expansion, coordinated movement of the sliding rods and the rotary shaft achieves dual-screen multi-angle positioning including a fully expanded multimedia mode and a vertical collaboration mode. This effectively solves the contradiction between fixed display angles and space utilization in traditional solutions, realizing collaborative optimization of the slidable dual-screen structure and the liquid cooling system.

### BRIEF DESCRIPTION OF THE DRAWINGS

FIG. 1 is a schematic diagram showing the multi-stage angle adjustable sliding dual-screen CPU liquid cooling heat dissipation device of the present invention achieving a 0° closed detent position.

FIG. 2 is a schematic diagram showing the multi-stage angle adjustable sliding dual-screen CPU liquid cooling heat dissipation device of the present invention achieving a 90° vertical detent position.

FIG. 3 is a schematic diagram showing the multi-stage angle adjustable sliding dual-screen CPU liquid cooling heat dissipation device of the present invention achieving a 120° display detent position.

FIG. 4 is an exploded view of the multi-stage angle adjustable sliding dual-screen CPU liquid cooling heat dissipation device of the present invention.

FIG. 5 is a perspective view of the multi-stage angle adjustable sliding dual-screen CPU liquid cooling heat dissipation device of the present invention.

### REFERENCE NUMBERS IN FIGURES

1 first display screen
2 second display screen
3 connecting rod
4 rotary shaft
5 slide rail
6 sliding rod
7 sliding member
8 spring post
9 lower plastic component

### DETAILED DESCRIPTION

In order to be able to understand the technical content of the present invention more clearly, the following embodiments are specifically described.

Before detailing the embodiments according to the present invention, it should be noted that, in the following context, the term “comprising”, “including”, or any other variation thereof is intended to cover non-exclusive inclusion, such that a process, method, article, or device comprising a series of elements includes not only those elements, but also other elements not explicitly listed, or elements inherent to such process, method, article, or device.

The multi-stage angle adjustable sliding dual-screen CPU liquid cooling heat dissipation device according to the present invention comprises:
a first display screen 1;
a second display screen 2 connected to the first display screen 1 via a rotary support structure;
a sliding linkage mechanism, cooperating with the rotary support structure, configured to achieve multi-stage angle adjustment between the first display screen 1 and the second display screen 2; and
a positioning mechanism disposed on the sliding linkage mechanism, wherein the positioning mechanism achieves tactile detent locking between the first display screen 1 and the second display screen 2 through a spring-ball structure provided thereon.

As a preferred embodiment of the present invention, the rotary support structure comprises a connecting rod 3 and a rotary shaft 4. One end of the connecting rod 3 is connected to the rotary shaft 4, and the other end is hingedly connected to a side wall of the first display screen 1. The rotary shaft 4 is disposed at an end of the sliding linkage mechanism and has a built-in damping mechanism.

As a preferred embodiment of the present invention, the sliding linkage mechanism comprises:
oppositely disposed slide rails 5;
sliding rods 6 disposed on the slide rails 5;
sliding members 7 slidably positioned through the slide rails 5 and the sliding rods 6, wherein an upper end of the sliding member 7 is hingedly connected to the side wall of the first display screen 1 and drives the first display screen 1 to slide along the slide rails 5; and
a spring assembly disposed on a lower surface of the slide rails 5, wherein the spring assembly cooperates with the sliding members 7 to enable tactile detent locking between the first display screen 1 and the second display screen 2.

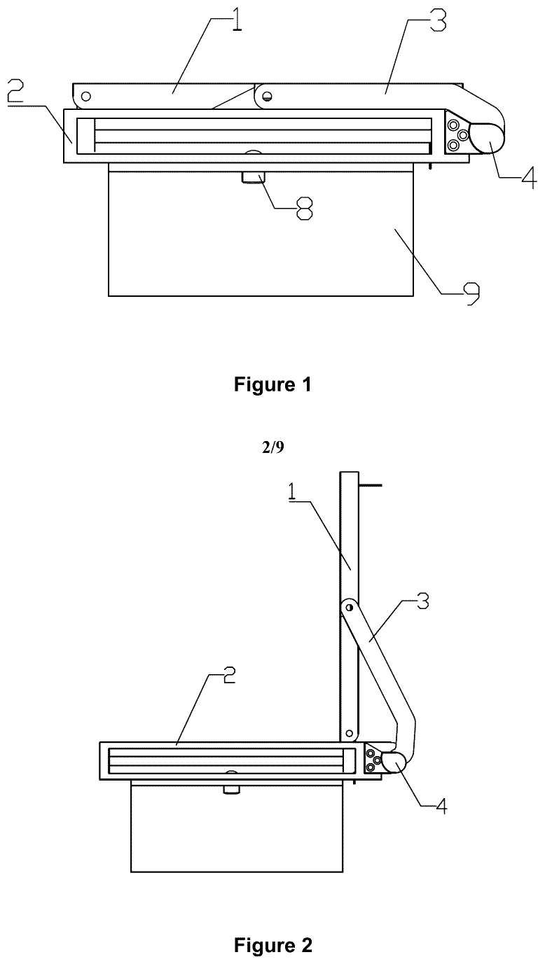

Please refer to FIG. 1. As a preferred embodiment of the present invention, when the sliding members 7 slide to a side away from the rotary shaft 4 and are engaged at ends of the slide rails 5, the connecting rods 3 are driven into a locked state by the first display screen 1, causing the first display screen 1 and the second display screen 2 to be in a first closed detent position (currently at 0°).

Please refer to FIG. 2. As a preferred embodiment of the present invention, when the sliding members 7 slide to a side close to the rotary shaft 4 and are engaged at terminal ends of the slide rails 5, the sliding members 7 drive the rotary shaft 4 to rotate, and drive the connecting rods 3 to position the side wall of the first display screen 1 perpendicular to the second display screen 2, causing the first display screen 1 and the second display screen 2 to be in a second closed detent position (currently at 90° vertical).

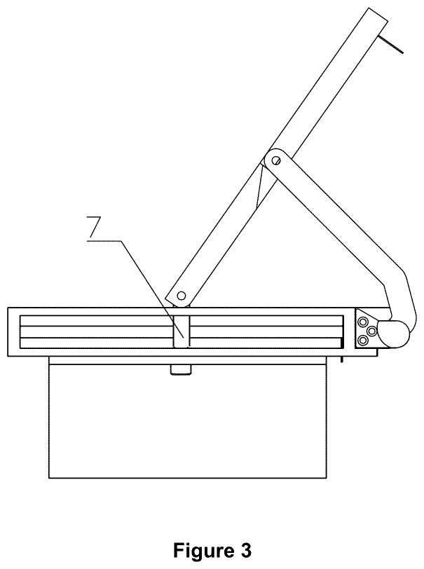

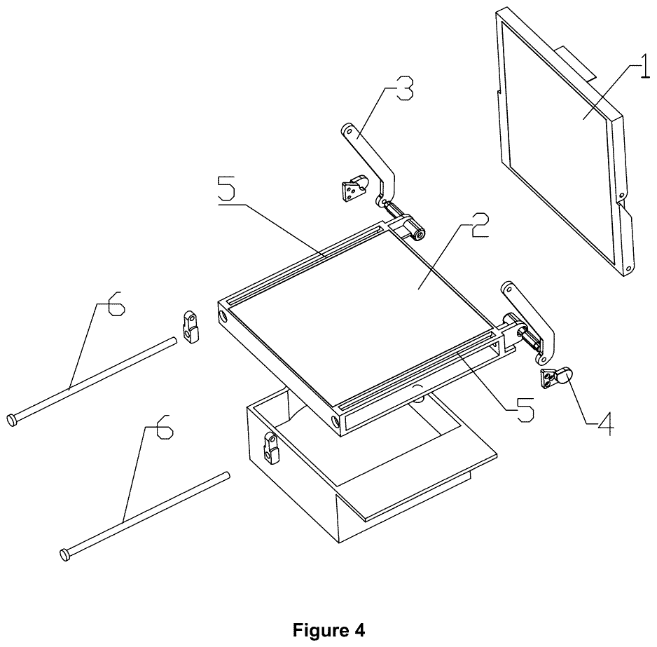

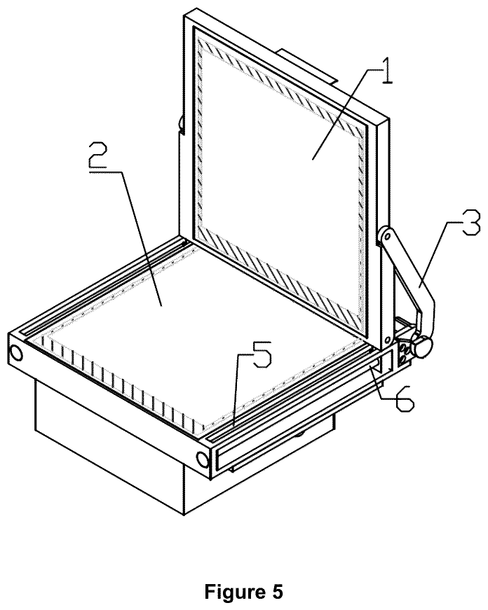

Please refer to FIG. 3. As a preferred embodiment of the present invention, the spring assembly comprises spring posts 8 and spring balls disposed therein. When the sliding members 7 slide to positions of the spring posts 8, the spring balls engage with the sliding members 7, thereby achieving tactile detent locking between the first display screen 1 and the second display screen 2, and placing the first display screen 1 and the second display screen 2 in a third closed detent position (currently at 120° display).

As a preferred embodiment of the present invention, a V-shaped heat dissipation space is formed between the first display screen 1 and the second display screen 2.

As a preferred embodiment of the present invention, PCB board are installed within both the first display screen 1 and the second display screen 2.

As a preferred embodiment of the present invention, the device is entirely fixed on a lower plastic component 9, and the lower plastic component 9 is fixed on a liquid cooling head.

In practical applications, the first display screen 1 and the second display screen 2 are connected via the connecting rods 3 and the rotary shaft 4. When closed, the first display screen 1 completely covers the second display screen 2 (achieving the 0° detent position); when unfolded, an included angle is formed between them.

The sliding rods 6 are made of alloy stainless steel with a diameter of 3 mm, penetrating through slide rail grooves on the side of the second display screen 2.

The lower surface of the slide rails 5 is provided with positioning points for the spring posts, which only position the display angle at 145° (a rotation of 35°).

The rotary shaft 4 has a built-in damping mechanism to ensure angle stability when the screen is unfolded. After manual pushing into position, the rotary shaft 4 automatically tightens the shaft and its connecting rods 3, ensuring the stability of the two screens at 90°.

The sliding members 7 are assembled with a clearance fit to the sliding rods 6 and cooperate with the balls of the slide rails to achieve tactile feedback for the detent position (145° display).

The principle for achieving multiple detent positions in the multi-stage angle adjustable sliding dual-screen CPU liquid cooling heat dissipation device of the present technical solution is as follows:
Closed Detent Position: The sliding members 7 engage into the ends of the slide rails 5, the rotary shaft 4 is in a locked state, and the second display screen 2 is completely hidden.
Vertical Detent Position: The sliding members 7 move to the tail ends of the slide rails 5, the rotary shaft 4 rotates, and the edge of the first display screen 1 becomes perpendicular to the second display screen 2, forming a locked structure.
Full Display Detent Position: The sliding members 7 reach the spring ball positions on the slide rails, locking the sliding members 7 in the detent position. At this time, the V-shaped space formed by the dual-screen assembly provides a directional channel for heat dissipation airflow.

In practical applications, the multi-stage angle adjustable sliding dual-screen CPU liquid cooling heat dissipation device of the present technical solution consists of two independent displays. When slid together (0 degrees), only the top screen displays. When side-slid open by 35° (display angle 145°), the upper screen displays fully, and the lower screen can display the visible area. When opened to 90°, both screens can display. It is understandable that the specific adjustment angles listed above are not limiting; the present technical solution only provides an illustrative description aimed at disclosing the implementation principle of multi-stage angle adjustment. Other adjustment angles not listed here should also fall within the protection scope of the present technical solution and will not be reiterated.

In a specific embodiment of the present invention, the first display screen 1 and the second display screen 2 are connected by two connecting rods 3 and two sliding members 7. The sliding members 7 can slide within the sliding rods 6 and the slide rails 5. The slide rails 5 and the sliding rods 6 have a limiting effect on the sliding members 7, allowing them to slide only linearly. The sliding members 7 pass through the sliding rods 6 and are movable. The sliding rods 6 are fixed to the frame of the second display screen 2. The spring posts 8 are also fixed to the second display screen 2. When the sliding members 7 move to the positions of the spring posts 8, the spring balls just engage with the sliding members, causing the first display screen 1 to stop free movement.

Simultaneously, this screen assembly is fixed on the lower plastic component 9, the lower plastic component 9 is fixed on the liquid cooling head, and two independent PCB board are located within their respective screen assemblies.

In practical applications, the first display screen 1 can be laterally displaced along the slide rails by 50-70 mm.

Driven by the sliding action of the sliding rods 6, the rotary shaft 3 drives the first display screen 1 to rotate by 3.6°.

The V-shaped space formed between the first display screen 1 and the second display screen 2 in the 120° unfolded state is used to directionally accelerate the airflow from the cooling radiator.

By adopting the multi-stage angle adjustable sliding dual-screen CPU liquid cooling heat dissipation device of the present invention, an independent dual-screen+slide rail linkage structure is specifically proposed. In the closed state, only the upper screen assembly is displayed. During side-sliding expansion, coordinated movement of the sliding rods and the rotary shaft achieves dual-screen multi-angle positioning including a fully expanded multimedia mode and a vertical collaboration mode. This effectively solves the contradiction between fixed display angles and space utilization in traditional solutions, realizing collaborative optimization of the slidable dual-screen structure and the liquid cooling system. In this specification, the present invention has been described with reference to its specific embodiments. However, it is apparent that various modifications and changes can still be made without departing from the spirit and scope of the present invention. Therefore, the description and drawings should be regarded as illustrative rather than restrictive.

1. A multi-stage angle adjustable sliding dual-screen CPU liquid cooling heat dissipation device comprises:
a first display screen;
a second display screen connected to the first display screen via a rotary support structure;
a sliding linkage mechanism, cooperating with the rotary support structure, configured to achieve multi-stage angle adjustment between the first display screen and the second display screen; and
a positioning mechanism disposed on the sliding linkage mechanism, wherein the positioning mechanism achieves tactile detent locking between the first display screen and the second display screen through a spring-ball structure provided thereon.

2. The multi-stage angle adjustable sliding dual-screen CPU liquid cooling heat dissipation device according to claim 1, wherein the rotary support structure comprises a connecting rod and a rotary shaft, wherein one end of the connecting rod is connected to the rotary shaft, and the other end is hingedly connected to a side wall of the first display screen; and wherein the rotary shaft is disposed at an end of the sliding linkage mechanism and has a built-in damping mechanism.

3. The multi-stage angle adjustable sliding dual-screen CPU liquid cooling heat dissipation device according to claim 2, wherein the sliding linkage mechanism comprises:
oppositely disposed slide rails;
sliding rods disposed on the slide rails;
sliding members slidably positioned through the slide rails and the sliding rods, wherein an upper end of the sliding member) is hingedly connected to the side wall of the first display screen and drives the first display screen to slide along the slide rails; and a spring assembly disposed on a lower surface of the slide rails, wherein the spring assembly cooperates with the sliding members to enable tactile detent locking between the first display screen and the second display screen.

4. The multi-stage angle adjustable sliding dual-screen CPU liquid cooling heat dissipation device according to claim 3, wherein when the sliding members slide to a side away from the rotary shaft and are engaged at ends of the slide rails, the connecting rods are driven into a locked state by the first display screen, causing the first display screen and the second display screen to be in a first closed detent position.

5. The multi-stage angle adjustable sliding dual-screen CPU liquid cooling heat dissipation device according to claim 3, wherein when the sliding members slide to a side close to the rotary shaft and are engaged at terminal ends of the slide rails, the sliding members drive the rotary shaft to rotate, and drive the connecting rods to position the side wall of the first display screen perpendicular to the second display screen, causing the first display screen and the second display screen to be in a second closed detent position.

6. The multi-stage angle adjustable sliding dual-screen CPU liquid cooling heat dissipation device according to claim 3, wherein the spring assembly comprises spring posts and spring balls disposed therein; and wherein when the sliding members slide to positions of the spring posts, the spring balls engage with the sliding members, thereby achieving tactile detent locking between the first display screen and the second display screen, and placing the first display screen and the second display screen in a third closed detent position.

7. The multi-stage angle adjustable sliding dual-screen CPU liquid cooling heat dissipation device according to claim 6, wherein a V-shaped heat dissipation space is formed between the first display screen and the second display screen.

8. The multi-stage angle adjustable sliding dual-screen CPU liquid cooling heat dissipation device according to claim 1, wherein PCB board are installed within both the first display screen and the second display screen.

9. The multi-stage angle adjustable sliding dual-screen CPU liquid cooling heat dissipation device according to claim 1, wherein the device is entirely fixed on a lower plastic component, and the lower plastic component is fixed on a liquid cooling head.
